(19) United States
(12) Patent Application Publication
(10) Pub. No.: US 2024/0186418 A1
(43) Pub. Date: Jun. 6, 2024

(54) DOUBLE-GATE FOUR-TERMINAL SEMICONDUCTOR COMPONENT WITH FIN-TYPE CHANNEL REGION

(71) Applicant: Brandenburgische Technische Universität Cottbus-Senftenberg, Körperschaft des Öffentlichen Rechts, Cottbus (DE)

(72) Inventors: Ulrich WULF, Cottbus (DE); Hans RICHTER, Frankfurt (Oder) (DE)

(21) Appl. No.: 18/552,811

(22) PCT Filed: Mar. 18, 2022
(86) PCT No.: PCT/EP2022/057201

§ 371 Date: Jan. 11, 2024

(30) Foreign Application Priority Data
Mar. 29, 2021 (DE) 10 2021 107 880.6

(51) Int. Cl. H01L 29/78; H01L 27/12; H01L 29/08

(52) U.S. Cl. CPC H01L 29/7855; H01L 27/1211; H01L 29/0847

(57) ABSTRACT

The disclosure relates to a double-gate four-terminal semiconductor component comprising a substrate, an electrically insulating cover layer on the substrate, a fin-type channel region situated above the substrate and composed of a doped semiconductor material of a first conductivity type having two mutually opposite longitudinal sides extending along a longitudinal direction of the channel region, the channel region having a first end and a second end in the longitudinal direction, a first and a second gate electrode, which are situated on the cover layer and are arranged opposite one another each on one of the longitudinal sides of the channel region and are each electrically insulated from the longitudinal sides by an insulation layer, a first and a second contact region situated on the cover layer and composed of a semiconductor material of a second conductivity type.

The present invention relates to semiconductor components with four contact regions and two independently controllable conductivity channels that are spatially separated by means of gate electrodes. Such devices are also referred to as double-gate four-terminal semi-conductor components. The invention further relates to a metal-oxide semiconductor logic circuit comprising at least one double-gate four-terminal semiconductor component.

The generation and control of conductivity channels in semiconductor components by means of the field effect is well known due to the great industrial importance of field effect transistors (FET) and technologically advanced in a wide variety of forms.

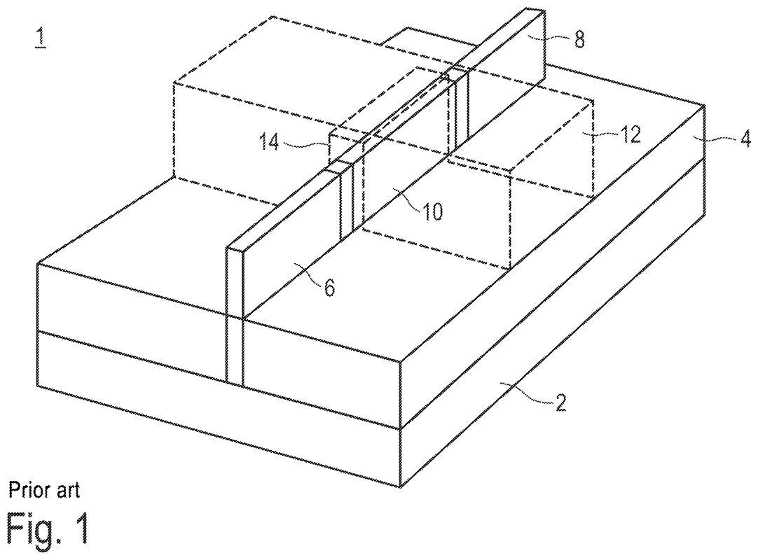

In the course of the constant efforts towards further miniaturization and functional development of semiconductor components, the FinFET structure 1 shown in FIG. 1 was developed. In the known FinFET structure 1 shown there, a channel region 10 arranged between a drain contact region 8 and a source contact region 6 is fin-shaped. The source contact region 6, the drain contact region 8 and the channel region 10 are arranged laterally side by side on a substrate 2 above a cover layer 4. Further, in order to form a conductivity channel in the channel region 10, a gate electrode 12 is arranged as a so-called gate-all-around structure around the channel region 10, separated from the latter only by an insulation layer 14. The channel region 10 is enclosed by the gate electrode 12 on three sides.

It is desirable to further miniaturize and enable an extended range of functions of a field effect transistor structure.

This object is achieved according to a first aspect of the invention by a double-gate four-terminal semiconductor component described in claim 1. A second aspect of the invention relates to a metal-oxide semiconductor logic circuit as claimed in claim 13. Firstly, however, the double-gate four-terminal semiconductor component of the first aspect of the invention is described in the following.

The double-gate four-terminal semiconductor component according to the invention comprises a substrate and an electrically insulating cover layer on the substrate.

Furthermore, the double-gate four-terminal semiconductor component comprises a fin-type channel region situated above the substrate and composed of a doped semiconductor material of a first conductivity type having two mutually opposite longitudinal sides extending along a longitudinal direction of the channel region, the channel region having a first end and a second end in the longitudinal direction.

In addition, the double-gate four-terminal semiconductor component comprises a first and a second gate electrode, which are situated on the cover layer and are arranged opposite one another each on one of the longitudinal sides of the channel region and are each electrically insulated from the longitudinal sides by an insulation layer.

In addition, the double-gate four-terminal semiconductor component comprises a first and a second contact region situated on the cover layer and composed of a semiconductor material of a second conductivity type, which are each arranged next to one of the gate electrodes toward the first end in the longitudinal direction of the channel region, each of the two contact regions being electrically conductively connected to the channel region and being electrically insulated from the adjacent gate electrode by an insulation layer.

Likewise, the double-gate four-terminal semiconductor component comprises a third and a fourth contact region situated on the cover layer and composed of a semiconductor material of the second conductivity type, which are each arranged next to one of the gate electrodes toward the second end in the longitudinal direction of the channel region, each of the two contact regions being electrically conductively connected to the channel region and being electrically insulated from the adjacent gate electrode by an insulation layer.

Furthermore, according to the invention, a transverse extent of the channel region in a transverse direction is dimensioned such that in a first operating state, in which a first and a second operating voltage are respectively applied to the gate electrodes, two conductivity channels of the second conductivity type separated by a barrier region in the transverse direction of the channel region are formed.

The invention is based on the recognition that further miniaturization of a FinFET structure is possible if, instead of only one conductivity channel, two conductivity channels can be formed within the fin-type conductivity region. According to the invention, instead of one gate electrode arranged around the channel region, two gate electrodes are used, which are arranged on mutually opposite longitudinal sides of the channel region. By applying a different operating voltage to the gate electrodes, it is possible to form two mutually independent conductivity channels within the channel region. By means of a suitable wiring configuration of the contact regions with a source voltage and a drain voltage, two independently operable field-effect transistor structures can be realized, which share the fin-type channel region.

Due to its structure, the double-gate four-terminal semiconductor component according to the invention, given suitable interconnection and activation in corresponding embodiments, can also realize a lateral current transport by means of a transverse resonant tunneling of charge carriers between the conductivity channels.

In the following, advantageous embodiments of the double-gate four-terminal semiconductor component are described.

In an advantageous embodiment of the double-gate four-terminal semiconductor component, the first and the third contact region are arranged as source contact regions on a first longitudinal side of the channel region. Furthermore, the second and fourth contact region are arranged as drain contact regions on a second longitudinal side of the channel region opposite the first longitudinal side. In addition, the transverse extent of the channel region and its doping are selected such that in a second operating state, in which a third and a fourth operating voltage are applied to each of the gate electrodes, the conductivity channels can be coupled to each other by a tunnel current of minority charge carriers through the barrier region.

By applying a suitable drain voltage to the drain contact regions and applying a suitable source voltage to the source contact regions, a highly effective, electrically controllable switch is obtained. By means of the gate electrodes, it is possible to control the tunnel current between the source contact region and the drain contact region and thus a switch state of the switch. Due to the resonant tunneling effect, this control is highly effective, so that small control voltage differences and therefore small amounts of dissipated power can be achieved.

In another advantageous exemplary embodiment of the double-gate four-terminal semi-conductor component, the first end of the channel region is a source end and the first and second contact region are source contact regions. In addition, the second end of the channel region is a drain end and the third and fourth contact regions are drain contact regions.

By applying a suitable drain voltage to the drain contact regions and applying a suitable source voltage to the source contact regions as well as suitable operating voltages to the gate electrodes, a bi-field effect transistor can be realized in which each of the gate electrodes together with the respective adjacent contact regions forms an independent field effect transistor. The conductor channels here are not connected by a tunnel current. By realizing two field effect transistors using only one fin-type channel region, a higher packing density of the field effect transistors can be achieved.

In an advantageous embodiment of the double-gate four-terminal semiconductor component, the transverse extent of the channel region and its doping are selected such that in a second operating state, in which a third and a fourth operating voltage are applied to each of the gate electrodes, the conductivity channels can be coupled to each other by a tunnel current of minority charge carriers through the barrier region. The possibility of generating a tunnel current through the barrier region allows the conductivity channels to be coupled to each other so that, for example, charge carriers that are induced in the adjacent conductivity channel through a source contact region are absorbed by the drain contact region adjacent to the other conductivity channel. This transverse tunnel current between mutually opposite source and drain contact regions is highly sensitive to the operating voltages of the gate electrodes. Small changes in the operating voltages of the gate electrodes lead to large changes in the current strength of the transverse tunnel current, which makes this embodiment a highly energy-efficient semiconductor component.

In a further embodiment of the double-gate four-terminal semiconductor component, the channel region has a height extent perpendicular to the cover layer, wherein a doping pro-file of the channel region has a doping starting from the substrate only up to a first height extent, and a height section from the first height extent to the maximum height extent of the channel region is undoped. In the region of the maximum height extent, wave functions of the minority charge carriers often have a greater extent from the gate electrodes in the transverse direction of the channel region than is the case in height sections closer to the substrate. Due to the claimed doping profile, a short circuit between the conductivity channels can be prevented due to the greater extent of the wave functions in the transverse direction in the region of the maximum height extent of the channel region.

In a further embodiment of the double-gate four-terminal semiconductor component, the channel region at the first end and at the second end each additionally comprises two channel arms that diverge in the transverse direction of the channel region and which are electrically insulated from the gate electrode by means of an insulation layer and to the end of which one of the contact regions is electrically conductively connected. The channel arms allow greater separation of opposite contact regions, which reduces crosstalk between the contact regions.

In a variant of this exemplary embodiment, corners of the gate electrodes which are adjacent to a channel arm and a longitudinal side of the channel region are rounded off in a plan view of the double-gate four-terminal semiconductor component. This has the advantage of providing better guidance of the minority charge carriers along the gate electrode from a contact region at one end of the channel region to a contact region at the other end of the channel region.

In another embodiment of the double-gate four-terminal semiconductor component, the cover layer has a recess, the channel region being at least partially arranged in the recess and with direct contact to the substrate. The direct contact of the channel region with the substrate has the advantage that when the substrate is earthed the channel region is also earthed.

In an alternative embodiment of the double-gate four-terminal semiconductor component to the previous embodiment, the cover layer is formed on the substrate as a continuous cover layer and the channel region is arranged on the cover layer. A continuous cover layer has the advantage of being simple to produce.

In a further embodiment of the double-gate four-terminal semiconductor component as claimed in at least one of the preceding claims, a dopant density of a conductivity doping of the channel region for achieving the first conductivity type is in the range between 10¹⁵ cm⁻³ and 10¹⁹ cm³. This dopant density is advantageous for enabling the formation of the separated conductivity channels. In particular, this dopant density is also advantageous for realizing a tunnel current between the conductivity channels.

In another embodiment of the double-gate four-terminal semiconductor component, the transverse extent of the channel region is in the range between 5 nm and 20 nm. A transverse extent with this dimension is advantageous for enabling the formation of the conductivity channels separated by the barrier region. Extents below 2 nm are also conceivable in principle, but require very high doping densities that are technically difficult to achieve.

In another embodiment of the double-gate four-terminal semiconductor component, the gate electrodes are arranged along the longitudinal sides of the channel region on a length, the size of which is greater than or equal to the sum of a coherence length of a wave function of the minority charge carriers within the channel region and double the shielding length of boundary fields generated by the contact regions within the gate electrode. The length of the gate electrodes is crucial to allowing the formation of resonant wave functions of the minority charge carriers within the channel region. The proposed dimension of the length extent meets this condition for both low and high minority carrier densities in the channel region.

In the following, the metal-oxide semiconductor logic circuit of the second aspect of the invention is described in more detail.

The metal-oxide semiconductor logic circuit comprises at least one double-gate four-terminal semiconductor component designed as a p-channel bi-field effect transistor, the first conductivity type of which being p-type and the second conductivity type being n-type, or at least one double-gate four-terminal semiconductor component designed as an n-channel bi-field effect transistor, the first conductivity type of which being n-type and the second conductivity type being p-type. The use of the double-gate four-terminal semiconductor component of the first aspect of the invention in metal-oxide semiconductor logic circuits is particularly advantageous since it enables a higher packing density of transistors compared to the prior art and can thus contribute to a higher level of integration of the metal-oxide semiconductor logic circuit.

In an advantageous embodiment, the metal-oxide semiconductor logic circuit is a PMOS, NMOS, or CMOS logic circuit.

In the following text further exemplary embodiments are described with reference to the figures. This is followed by a brief description of the figures.

FIG. 1 shows a FinFET structure from the prior art;

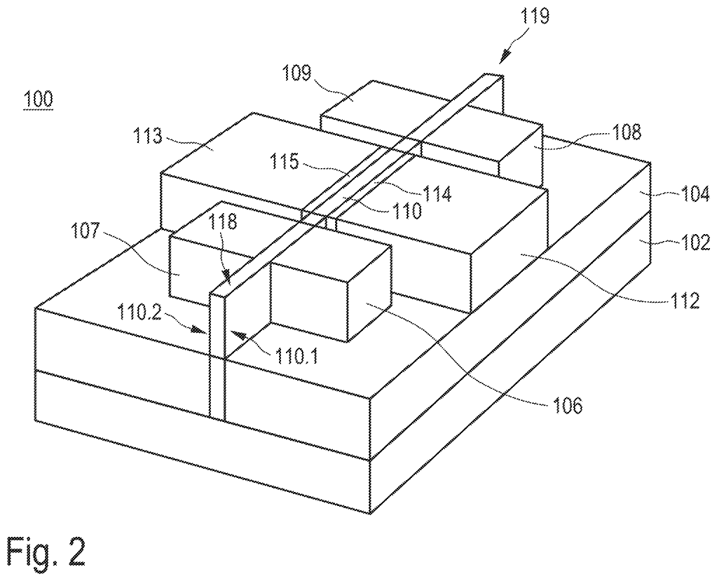

FIG. 2 shows an exemplary embodiment of a double-gate four-terminal semiconductor component;

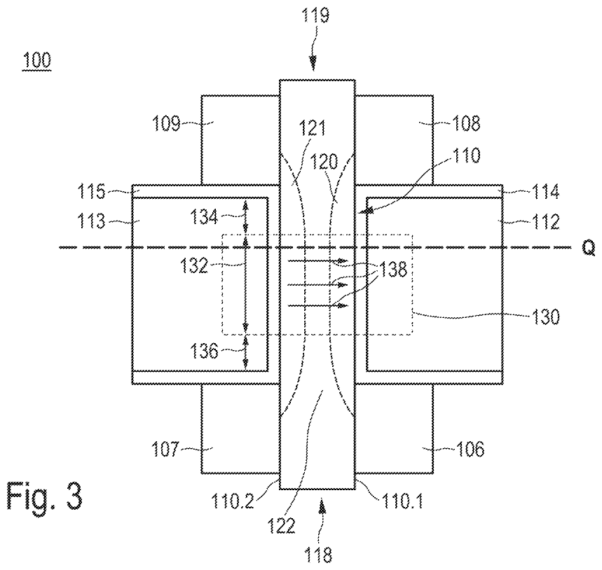

FIG. 3 shows a plan view of the double-gate four-terminal semiconductor component from FIG. 2;

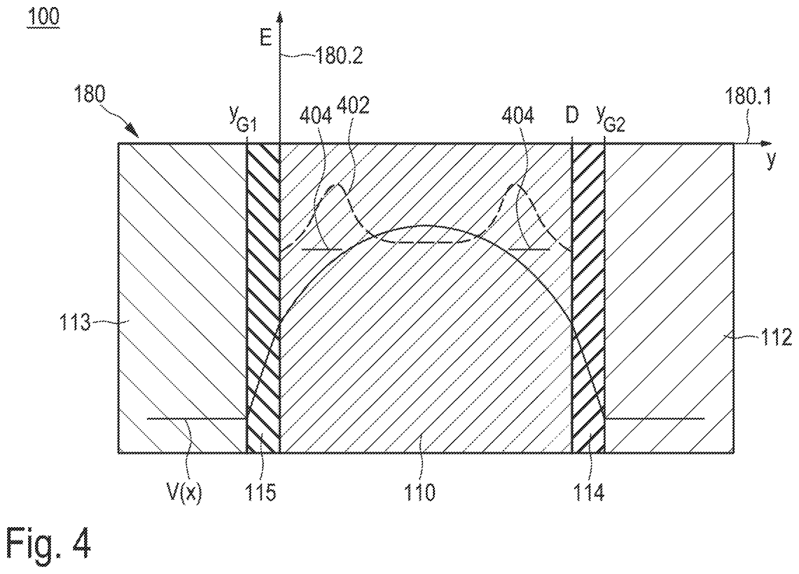

FIG. 4 shows the channel region and gate electrodes of the double-gate four-terminal semiconductor component from FIG. 2 and FIG. 3 in cross-section;

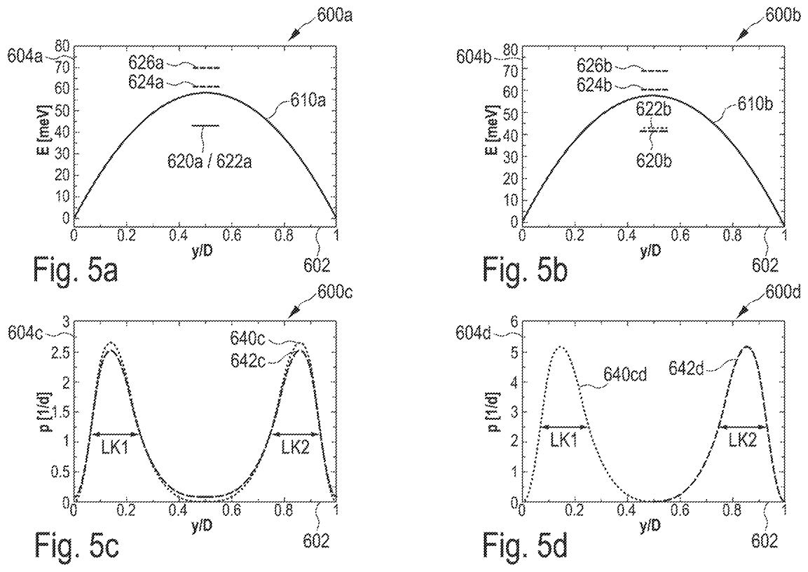

FIG. 5a shows a first graph, in which examples of potential barriers and energy eigenlevels of electrons in the channel region are shown for a case without trans-verse voltage;

FIG. 5b shows a second graph, in which examples of potential barriers and energy eigenlevels of electrons in the channel region are shown for a case with transverse voltage;

FIG. 5c shows a third graph, in which probability distributions for the lowest two energy levels are shown for the example from FIG. 5a;

FIG. 5d shows a fourth graph, in which probability distributions for the lowest two energy levels are shown for the example from FIG. 5b;

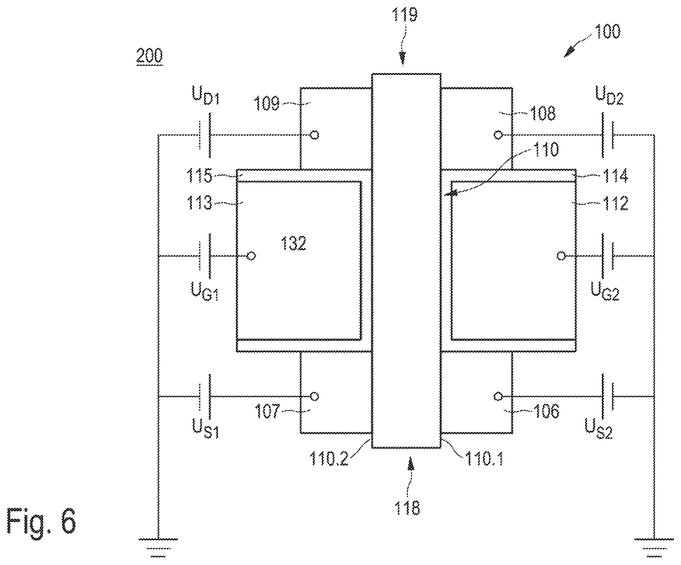

FIG. 6 shows a wiring configuration 200 of the double-gate four-terminal semiconductor component from FIG. 1 with a number of voltage sources.

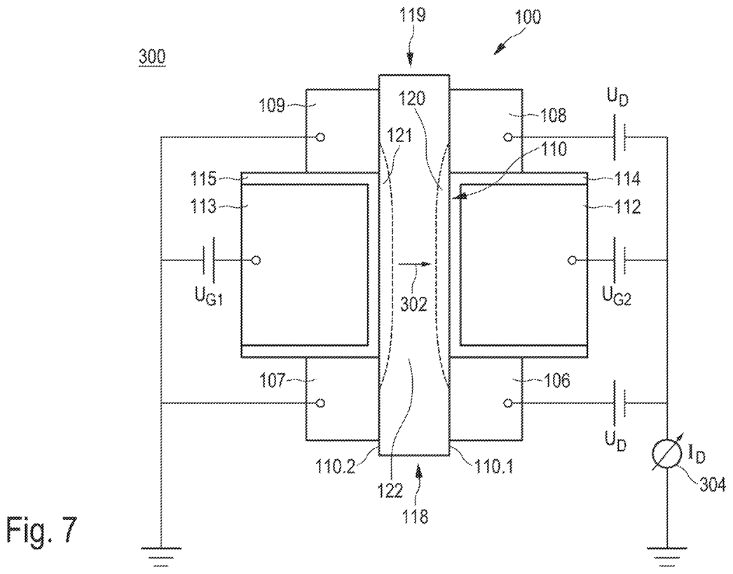

FIG. 7 shows a wiring configuration 300 of the double-gate four-terminal semiconductor component from FIG. 1 with a number of voltage sources.

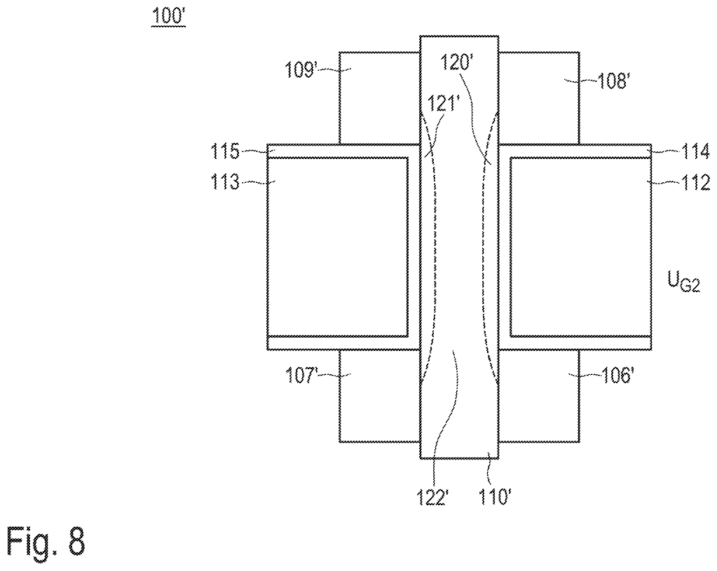

FIG. 8 shows a p-channel double-gate four-terminal semiconductor component in plan view;

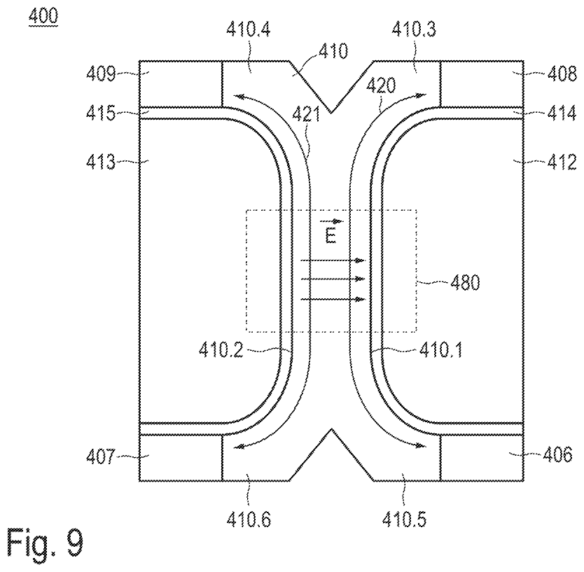

FIG. 9 shows a p-channel double-gate four-terminal semiconductor component with connecting arms in plan view;

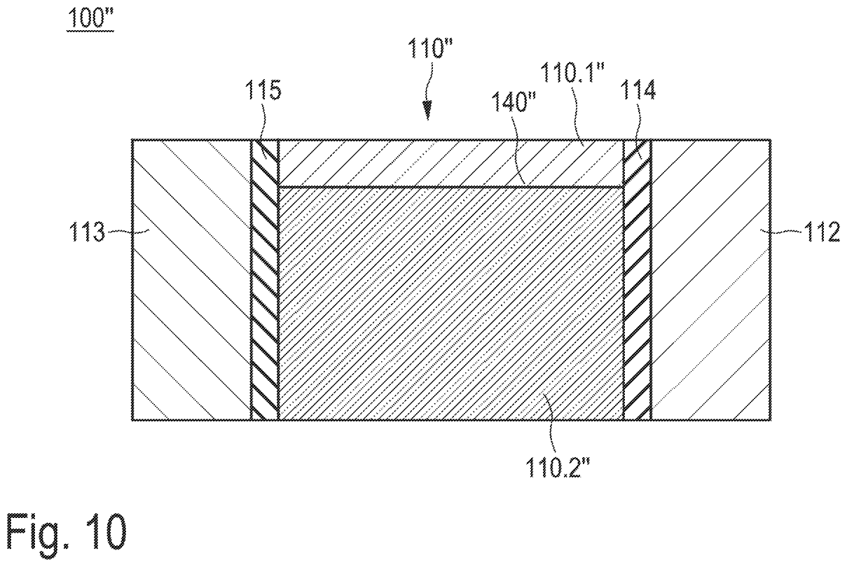

FIG. 10 shows a cross-sectional view of an n-channel double-gate four-terminal semiconductor component with an adjusted doping profile of the channel region;

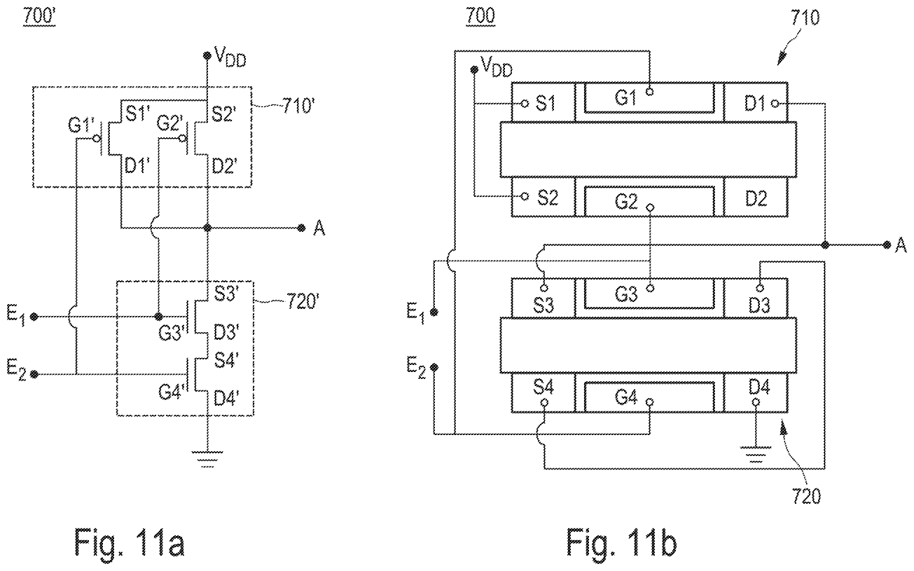

FIG. 11a shows a circuit diagram of a NAND gate in CMOS technology according to the prior art; and

FIG. 11b shows a NAND gate according to the circuit diagram of FIG. 11a, which is realized with a p-channel double-gate four-terminal semiconductor component and an n-channel double-gate four-terminal semiconductor component according to the present invention.

In the following, FIGS. 2 to 11b are described in detail.

FIG. 2 shows an exemplary embodiment of a double-gate four-terminal semiconductor component 100. The double-gate four-terminal semiconductor component 100 comprises a substrate 102 and a fin-type channel region 110 applied to the substrate. The channel region 110 consists of a p-doped semiconductor material and has two mutually opposite longitudinal sides 110.1 and 110.2 extending along a longitudinal direction of the channel region 110. Also arranged on the substrate 102 is an insulating cover layer 104, which surrounds the channel region 110.

The double-gate four-terminal semiconductor component 100 further comprises two gate electrodes 112 and 113, which are arranged on the cover layer 104 and opposite each other along the longitudinal sides 110.1 and 110.2 of the channel region 110. The gate electrodes 112 and 113 are electrically insulated from the channel region 110 by the insulation layers 114 and 115.

Furthermore, the double-gate four-terminal semiconductor component 100 comprises four contact regions of an n-doped semiconductor material arranged on the cover layer 104. A first and a second contact region 106 and 107 are arranged at a first end 118 of the channel region 110 and a third and a fourth contact region 108 and 109 at a second end 119 of the channel region 110. The contact regions 106 and 107 are arranged opposite each other on mutually opposite longitudinal sides of the channel region 110 and connected to these in an electrically conductive manner. The same applies to the contact regions 108 and 109. Furthermore, one of the gate electrodes 112 or 113 is situated between contact regions each arranged on a longitudinal side of the channel region 110.

In the embodiment 100 of the double-gate four-terminal semiconductor component shown in FIG. 2, the channel region 110 is arranged in a recess of the cover layer 104 on the substrate 102. In other embodiments, which are not shown here, however, the cover layer 104 is continuous, whereby the channel region 110 is arranged on the cover layer and is not in direct contact with the substrate 102.

Connection of the contact regions 106-109 and the gate electrodes 112 and 113 to voltage sources is usually carried out by means of electrical terminals. However, for improved clarity these are not shown in FIGS. 2-4.

Due to the selected doping of the channel region 110 and the doping of the contact regions 106-109, there is initially no electrically conductive connection between the contact regions. Only by applying an operating voltage to one of the gate electrodes 112 or 113 can one or two conductivity channels be formed for the minority charge carriers of the channel region 110, which connects contact regions located on the same longitudinal side of the channel region to each other in an electrically conductive manner. The two conductivity channels are described in detail below with reference to FIG. 3.

FIG. 3 shows a plan view of the double-gate four-terminal semiconductor component 100 from FIG. 2. All elements of the double-gate four-terminal semiconductor component 100, which have already been described in relation to FIG. 2, are provided with the same reference sign as in FIG. 2 and are not described again in the following.

FIG. 3 shows the double-gate four-terminal semiconductor component 100 in an operating state in which an operating voltage is applied to each gate electrode 113 and 112, which causes a displacement of the majority charge carriers of the channel region 110 from the longitudinal sides towards the center of the channel region 110. The conductivity channels formed thereby are provided with the reference signs 120 and 121 respectively in FIG. 3. As can be seen from the figure, the conductivity channels 120 and 121 extend in the longitudinal direction of the channel region 110 beyond the contact regions with the gate electrodes 112 and 113, so that the conductivity channels 120 and 121 each produce an electrically conductive connection between the contact region 106 and the contact region 108 and between the contact region 107 and the contact region 109. In the transverse direction of the conductor channel 110, the two conductivity channels 120 and 121 are separated by a non-conductive barrier region 122. The extent of the barrier region 122 in the transverse direction of the channel region 110 is determined by the operating voltages applied to the gate electrodes 112 and 113.

Furthermore, FIG. 3 shows that in the case of the double-gate four-terminal semiconductor component 100, when operating voltages are applied to the gate electrodes 112 and 113 in the region 130, a particularly homogeneous electric field is formed, which is represented by the three arrows labeled with 138. This homogeneous electric field is important for the formation of a resonant tunnel current between the conductivity channels 120 and 121, which will be discussed in more detail later. The region 130 is located at a shielding distance 134 or 136 from the contact regions adjacent to the gate electrodes. The shielding distance is determined by the shielding length, which specifies a penetration depth into the gate electrode above which an electric field of a contact region is attenuated to such an extent that its effect on the electric field of the gate electrode is negligible.

In order for a resonant tunnel current to form, it is additionally advantageous if a longitudinal extent of the gate electrodes in the longitudinal direction of the channel region 110 corresponds to at least twice the shielding length plus a coherence wavelength of a wave function of a minority charge carrier in the channel region 110. The coherence wavelength in this case depends on the electron density in the channel. To a rough approximation, the value for the coherence wavelength can be estimated at 30 nm. The shielding length can be estimated as a width of the channel region in the transverse direction.

Furthermore, it is also possible for a tunnel current to form between the two conductivity channels. The following text, with reference to FIG. 4 and FIGS. 5a-5d, describes the mechanisms specifically involved in the formation of the conductivity channels and the tunnel current between the conductivity channels.

FIG. 4 shows the channel region 110 and gate electrodes 112 and 113 of the double-gate four-terminal semiconductor component 100 from FIG. 2 and FIG. 3 in cross-section. The cross-section runs along a line Q drawn in FIG. 3. All elements of the double-gate four-terminal semiconductor component 100, which have already been described with reference to FIG. 2 or FIG. 3, are also provided with the same reference sign in FIG. 4 and are not described again in the following.

In cross-section, the channel region 110 and the gate electrodes 112 and 113 arranged along the sides of the channel region 110 are shown with the corresponding insulation layers 114 and 115.

Furthermore, the structural elements shown are supplemented by a coordinate system 180 with two axes 180.1 and 180.2. The axis 180.1, also labeled with a “y” and hereafter referred to as the y-axis, indicates the extent of the structural elements shown in the transverse direction to the channel region. Axis 180.2, also labeled with “E” and hereafter referred to as the energy axis, is used to represent energy values of potential and eigenfunctions in the region of the channel region 110.

The y-axis has its zero point at an interface between channel region 110 and insulation layer 115. A position of a boundary layer between gate electrode 113 and insulation layer 115 is labeled as y_{G1} and a position of a boundary layer between gate electrode 112 and insulation layer 114 is labeled as y_{G2}. A transverse extent of the channel region 110 is given by D.

FIG. 4 shows, by way of example, the state of the double-gate four-terminal semiconductor component 100 when positive voltages are applied to both gate electrodes 112 and 113. The applied positive voltages and the resulting charge displacement within the channel region 110 give rise to the formation of the electrostatic potential labeled as V(y). As can be seen from FIG. 4, the electrostatic potential V(y) is constant in the region of the gate electrode 113, then increases linearly in the region of the insulation layer 115 and then parabolically within the channel region 110 to a maximum value, before it then falls again to a constant value in the gate electrode 112. Within the channel region 110, the electrostatic potential is mirror-symmetric with respect to a vertical plane in a center of the channel region 110.

By means of quantum mechanical calculations it is possible to determine the eigenfunctions and eigenvalues of the electrons in the channel region 110. As an example, FIG. 4 shows a probability distribution 402 of the electrons within the channel region 110 for the lowest eigenvalue, and the eigenvalue 404 itself. As can be seen in FIG. 4, the eigenvalue 404 is below the maximum of the electrostatic potential V(y), which causes localization of the electrons within the channel region 110. Furthermore, it is apparent from FIG. 4 that the probability distribution 402 has a maximum on both the right and on the left side of the channel region 110. These two maxima lead to the formation of the two conductivity channels, as shown in FIG. 3. Furthermore, FIG. 4 shows that the probability distribution between the maxima is non-zero, which leads to the resonant tunnel current described in relation to FIG. 3. Under certain circumstances, however, it is also possible that the two maxima in the probability distribution are not coupled to each other. In order to understand the function of the double-gate four-terminal semiconductor component in this respect, a detailed examination of the properties of the electronic eigenvalues and eigenfunctions is necessary. This is explained in depth below with reference to FIGS. 5a-5d. In particular, it will be shown under which conditions a tunnel current can be realized between the channels.

Calculations of the extent of the conductivity channels as well as an estimation of the tunnel current are based on theoretical considerations, which are presented in the first part of this analysis. Subsequently, in a second part, results of these theoretical considerations on the system of the double-gate field effect transistor shown in FIG. 4 will then be shown.

Two core areas are relevant for the theoretical considerations: the determination of an expression for the electrostatic potential inside the channel region and the subsequent solution of the time-independent Schrödinger equation for determining the electronic eigenfunctions.

The electrostatic potential V(x) can be calculated using the Poisson equation with depletion approximation:

$$\begin{matrix}\frac{{d}^{2}}{{dy}^{2}} V ( y ) = - \frac{e}{{κ}_{0} κ} {N}_{A} Θ ( y ) Θ ( D - y ) . & for & {y}_{GI} \leq y \leq {y}_{G 2}\end{matrix} \qquad ( 1 )$$

Here D is the extent in the transverse direction of the fin-shaped channel region and y_{G1} and y_{G2} are the positions of the interfaces of the gate electrode and the insulation layer, as are also shown in FIG. 4. In addition, κ is the dielectric constant of the substrate and κ₀ the permittivity of the vacuum.

In depletion approximation, all dopants, here acceptors of density N_{A}, are assumed to be ionized. This assumption is justified because the positive voltages applied at the gate electrodes lead to a reduction in the band energies, while the chemical potential in substrate 102 remains the same. It is assumed that the substrate is earthed and voltages are applied relative to earth. In depletion approximation, the free charge carriers are also neglected.

To solve the Poisson equation (1), Dirichlet boundary conditions must be applied, which have the following form:

V(y_{G1})=−eU′_{G1}=−e(U_{G1}−U₁^{FB}) and V(y_{G2})=−eU′_{G2}=−e(U_{G2}−U₂^{FB}). (2)

Here U₁^{FB} and U₂^{FB} are flatband voltages, which are defined as follows:

−e,U₁^{FB}=μ−μ_{G1} and −eU₂^{FB}=μ−μ_{G1}. (3)

Calculation shows that in the region of the fin-type channel region, the solution of the Poisson equation (1) with the boundary conditions (2) is as follows:

$$V ( y ) = - \frac{C}{2} {y}^{2} + α y + β \qquad ( 4 )$$

wherein the following also apply:

$$C = \frac{1}{{κ}_{0}} \frac{{N}_{A} {e}^{2}}{κ} , \qquad ( 5 )$$

$$α = \frac{{CD}^{2} / 2 + {κ}_{2} {CDD}_{2} + e ( {U}_{G 1}^{′} - {U}_{G 2}^{′} )}{D + {κ}_{2} {D}_{2} + {κ}_{1} {D}_{1}} = \frac{C D}{2} + \frac{e ( {U}_{G 1}^{′} - {U}_{G 2}^{′} )}{D + 2 {κ}_{0} {D}_{0}} \qquad ( 6 )$$

$$β = {κ}_{0} α {D}_{0} - {eU}_{G 1}^{′} . \qquad ( 7 )$$

Here D₁=−y_{G1} and D₂=y_{G1}−D are the widths of the respective insulation layers with the dielectric constants κ_{G1} and κ_{G2}, and κ₁=κ/κ_{G1} and κ₂=κ/κ_{G2}.

For the purpose of simplifying the time-independent Schrödinger equation for the electrons in the channel region, the following only considers the special case of a symmetrical system with D₁=D₂=D₀ and κ₁=κ₂=κ₀. With this simplification, the time-independent Schrödinger equation in the region of the channel region is:

$$( - \frac{ℏ}{2 {m}^{*}} \frac{{d}^{2}}{{dy}^{2}} {\underbrace{- \frac{C}{2} {y}^{2} + α y + β}}_{V ( y )} - {E}_{n} ) {ψ}_{n} ( y ) = 0 ⇔ ( - \frac{{d}^{2}}{{du}^{2}} - \frac{c}{2} {u}^{2} + a u + b - {ϵ}_{n} ) {ψ}_{n} ( u ) = 0. \qquad ( 8 )$$

where ψₙ(y)=ψₙ(u) is a transverse component of the wave function with a length normalization u=y/D and an energy normalization ϵ=E/E₀, where

$${E}_{0} = \frac{ℏ}{2 {m}^{*}} {( \frac{1}{D} )}^{2} . \qquad ( 9 )$$

In addition, for the constants introduced in the second part of equation (8):

$$c = \frac{{CD}^{2}}{{E}_{0}} = \frac{{e}^{2} {N}_{A}}{{κ}_{0} κ} {D}^{2} \frac{2 {m}^{*}}{{ℏ}^{2}} {D}^{2} = 2 \frac{{e}^{2} {N}_{A} {D}^{4} {m}^{*}}{{κ}_{0} {κℏ}^{2}} , \qquad ( 10 )$$

$$a = \frac{Dα}{{E}_{0}} = \frac{D}{{E}_{0}} [ \frac{CD}{2} + \frac{e ( {U}_{G 1}^{′} - {U}_{G 2}^{′} )}{D + {2}_{{κ}_{0}} {D}_{0}} ] = \frac{c}{2} - \frac{Δ V}{1 + {κ}_{0} \frac{{D}_{0}}{D}} \qquad ( 11 )$$

$$with - {eU}_{G 1} / {E}_{0} = {V}_{1} , - e {U}_{G 1} / {E}_{0} = {V}_{2} and ΔV = {V}_{1} - {V}_{2} , and$$

$$b = \frac{β}{{E}_{0}} = \frac{{κ}_{0} α {D}_{0} - {eU}_{G 1}^{′}}{{E}_{0}} = {κ}_{0} {d}_{0} a + {V}_{1} \qquad ( 12 )$$

with d₀=D₀/D. By estimating the constants a, b and c, equations (10)-(12) can be further simplified. Thus for the constants c and E₀ for a Si substrate:

$$c = {n}_{A} {d}^{4} {m}_{y} \times 370 \qquad ( 13 )$$

$${E}_{0} = \frac{1}{{m}_{y} {d}^{2}} 0.375 meV ≡ {e}_{0} \times 1 meV \qquad ( 14 )$$

with the effective mass m_{y} in the transverse direction of the channel region (m*=m_{y}m₀=m_{y}×9.1×10⁻³¹ kg), N_{A}=n_{A}×10²⁴ m⁻³=n_{A}×10¹⁸ cm⁻³ and D=d×10⁻⁸. From equation (11) and equation (12) we thus obtain:

$$a = \frac{c}{2} - \frac{D}{{E}_{0}} \frac{e ( {U}_{G 1}^{′} - {U}_{G 2}^{′} )}{D + {2}_{{κ}_{0}} {D}_{0}} = \frac{c}{2} - \frac{{u}_{1} - {u}_{2}}{{e}_{0}} \frac{1}{1 + {κ}_{0} \frac{{D}_{0}}{D}} \qquad ( 15 )$$

$$b = {κ}_{0} {d}_{0} a + \frac{{u}_{1}}{{e}_{0}} . \qquad ( 16 )$$

Here u₁ and u₂ are the applied gate voltages eU_{G1} and eU_{G2} in meV.

Using the derived equations, examples of electronic eigenfunctions and eigenvalues will now be calculated based on FIGS. 5a-5d for the system shown in FIG. 4, wherein the following system parameters are assumed: transverse extent in the transverse direction of the channel region D=15 nm, thickness of the insulation layers D₀=4 nm, k₀=3.9, N_{A}=1.5×10¹⁸ cm⁻³ and m_{y}=0.91.

Equations (13), (15) and (16) show that the potential V(y) in equation (8) essentially depends only on the voltage difference between the two voltages applied to the gate electrodes. The absolute value u₁ is input into the parameter b according to eq.(16). In equation (8), however, b is only a potential constant that can be absorbed into a suitable energy normalization. For a fixed value of b the voltages applied to the contact regions should be selected in such a way that states with energies less than the maximum of V(y) are occupied (see for example 620a and 622a in FIG. 5a) and states with energies greater than the maximum of V(y) are unoccupied (see for example 624a and 626a in FIG. 5a). FIG. 5a shows a first graph 600, in which examples of potential barriers and energy eigenlevels of electrons in the channel region are shown for a case without transverse voltage. The absence of a transverse voltage here means that the applied voltages at the opposite gate electrodes are identical.

The graph 600a is plotted on two axes. Along an axis 602, also labeled as y and hereafter also referred to as the y-axis, a position normalized to the transverse extent D in the transverse direction within the channel region 110 is plotted. Energy is plotted along a second axis 604a, also labeled as E and hereafter also referred to as the energy axis.

Graph 600a shows the electrostatic potential, provided with a reference sign 610a, for the region of the channel region and the four lowest energy eigenvalues of the electrons, provided with the reference signs 620a, 622a, 624a and 626a. The lowest energy eigenvalues 620a and 620b are degenerate and located, as is apparent in FIG. 5a, below the potential 610a.

FIG. 5c shows a third graph 600c, in which probability distributions for the lowest two energy levels are shown for the example from FIG. 5a.

The graph 600c is plotted on two axes. As before, along axis 602 a position normalized to the transverse extent D in the transverse direction within the channel region 110 is plotted. Along an axis 604c, also labeled as ρ, a probability density of the presence of minority charge carriers within the channel region is plotted.

As has already been discussed, diagram 600c shows that the electrons in the two lowest energy eigenvalues are mainly limited to the region between the insulation layers and the maximum of the potential and thus form the conductivity channels at the edges of the channel region. This is also indicated by the arrows labeled LK1 and LK2.

Furthermore, it can be seen that the probability distribution of the electrons of the lowest two eigenvalues extends over both conductivity channels. This means that by applying identical voltages to the gate electrodes, a tunnel current is produced between the conductivity channels. The behavior is different if a voltage difference exists between the voltages applied to the gate electrodes.

FIG. 5b shows a second graph 600b, in which examples of potential barriers and energy eigenlevels of electrons in the channel region 110 are shown for the case with transverse voltage.

The graph 600b is plotted on two axes. Along axis 602 a position normalized to the transverse extent D in the transverse direction within the channel region 110 is plotted. Energy is plotted along a second axis 604b, also labeled as E and hereafter also referred to as the energy axis.

The transverse voltage on which graph 600b is based is only 4 meV. As can be seen in FIG. 5b, this only gives rise to a slightly asymmetric potential 610b, which deviates only slightly from the potential 610a. In particular, in this case also, the lowest two eigenvalues 620b and 622b are energetically below the potential 610b. However, it is clear that the transverse voltage leads to a reversal of the degeneration of the lowest energy levels.

FIG. 5d shows a fourth graph 600d, in which probability distributions for the lowest two energy levels are shown for the example from FIG. 5b.

The graph 600d is plotted on two axes. As before, along axis 602 a position normalized to the transverse extent D in the transverse direction within the channel region 110 is plotted. Along an axis 604d, also labeled as ρ, a probability density of the presence of minority charge carriers within the channel region 110 is plotted.

As shown in diagram 600d, a probability distribution 642d of the eigenvalue 620b primarily extends over the right conductor channel, while a probability distribution 640d of the eigenvalue 622d primarily extends over the left conductor channel. The transverse voltage thus prevents the electrons from tunneling from one conductivity channel to the other. This also shows the advantage of this invention, which consists, among other things, of the fact that a transverse voltage of just a few millielectron-volts is sufficient to switch between an operating mode with tunnel current and an operating mode without tunnel current.

Furthermore, it is of course also possible to produce only one conductivity channel by applying an operating voltage to only one gate electrode. The conductivity channels can therefore be generated independently of each other.

Crucial to the formation of two separate conductor channels is the curvature of the potential V(y), which is expressed by the parameter c in eq. (13). The greater c, the greater the curvature, and the more likely the formation of separate channels. Equation (13) shows that the smaller the width d of the channel region 110 is chosen, the higher the doping must be. FIG. 5 shows a situation with a minimum possible parameter c: the two conductor channel states 620a and 622a are separated from the higher extended states 624a and 626a by approximately the thermal energy k_{B}T. If the chemical potential in the contact regions is then chosen in the order of magnitude of 40 meV, the conductor channel states are occupied and the extended states are not. With a smaller curvature parameter, the extended states are increasingly occupied and a non-resonant transverse conductivity is obtained. Analogous considerations also apply to the conductivity channels shown in FIG. 5a and FIG. 5c that are connected to a tunnel current.

In FIG. 5, the doping density is N_{A}=10¹⁸ cm⁻³ and D=15 nm. Assuming a technically maximum possible doping density of N_{A}=10¹⁹ cm⁻³, the same curvature parameter c is obtained at a minimum channel width of D˜8 nm. Assuming a maximum effective coherence length of the wave functions of 30 nm and selecting D=30 nm, a minimum doping density of N_{A}=6*10¹⁶ cm⁻³ is obtained. These are technically feasible values.

The explanations up to now for the double-gate four-terminal semiconductor component have concentrated mostly on the charge carrier distribution within the channel region 110. In the following, with reference to FIG. 6 and FIG. 7, the options for interconnecting the contact regions will be discussed in more detail.

FIG. 6 shows a wiring configuration 200 of the double-gate four-terminal semiconductor component 100 from FIG. 1 with a number of voltage sources.

The double-gate four-terminal semiconductor component 100 shown in FIG. 6 corresponds to the semiconductor component already described based on FIG. 1. The components of the double-gate four-terminal semiconductor component 100 already described with reference to FIG. 1 have been provided with the same reference signs in FIG. 6. These components will not be described again in the following.

In the wiring configuration 200, the gate electrode 112 has an operating voltage U_{G2} applied to it and the gate electrode 113 an operating voltage U_{G1}. As already explained in relation to FIG. 3, two independently controllable conductivity channels can be formed along the gate electrodes by means of the applied operating voltage U_{G1} and U_{G2}.

Furthermore, in the wiring configuration 200, an operating voltage U_{S2} is applied to the contact region 106, an operating voltage U_{S1} to the contact region 107, an operating voltage U_{D2} to the contact region 108 and an operating voltage U_{D1} to the contact region 109. Due to the choice illustrated for the polarity of the operating voltages U_{S1}, U_{S2}, U_{D1} and U_{D2}, the contact regions 106 and 107 correspond to source contact regions and the contact regions 108 and 109 to drain contact regions. The first end 118 of the channel region 110 thus corresponds to a source end and the second end 119 of the channel region 110 corresponds to a drain end. In the non-resonant case, i.e. when U_{G1} and U_{G2} are chosen in such a way that there is no tunnel current between the conductivity channels, the drain contact region 106, source contact region 108, gate electrode 112 and source contact region 107, drain contact region 109, gate electrode 113 each form an independent field effect transistor. The double-gate four-terminal semiconductor component 102 is therefore also referred to as a bi-field effect transistor. In the case of a resonant coupling between the conductivity channels, the double-gate four-terminal semiconductor component 100 forms a two-channel quantum quadripole.

FIG. 7 shows a wiring configuration 300 of the double-gate four-terminal semiconductor component 100 from FIG. 1 with a number of voltage sources.

In the wiring configuration 300, an operating voltage U_{G1} and U_{G2} is applied to the gate electrodes 112 and 113 respectively, which can therefore be controlled independently of each other. The contact regions 107 and 109 are short-circuited and earthed. They act as source contact regions. In addition, an operating voltage U_{D} is applied to the contact regions 106 and 108, which act as drain contact regions.

Given a suitable choice of the operating voltages U_{G1} and U_{G2}, the two channel regions 120 and 121 are formed, which can be coupled together with a resonant tunnel current 302. An electrically controlled switch is created, wherein the resonant tunnel current 302 between source and drain is controlled by the operating voltages U_{G1} and U_{G2}. Due to the resonant tunneling effect, this control is highly effective, so that small control voltage differences and therefore small amounts of dissipated power can be achieved. An ammeter 304 shown in FIG. 7 can be used to determine a current I_{D}, which is proportional to the tunnel current 302.

In FIGS. 2-7, so far only an n-channel double-gate field effect transistor 100 has been described. However, the equations derived in relation to FIG. 5a-5d are also valid for p-channel double-gate four-terminal semiconductor components constructed in a similar manner. In the following, therefore, such a p-channel double-gate four-terminal semiconductor component is described with reference to FIG. 8.

FIG. 8 shows a p-channel double-gate four-terminal semiconductor component 100′ in plan view.

The p-channel double-gate four-terminal semiconductor component 100′ differs from the n-channel double-gate four-terminal semiconductor component 100 only in the doping of the channel region and the source and drain contact regions. For this reason, elements of the p-channel double-gate four-terminal semiconductor component 100′ which are identical to those of the n-channel double-gate four-terminal semiconductor component 100 are provided in FIG. 8 with the same reference signs and are not further explained below.

The p-channel double-gate four-terminal semiconductor component 100′ comprises a fintype channel region 110′ consisting of an n-doped semiconductor material. Furthermore, the p-channel double-gate four-terminal semiconductor component 100′ has four contact regions 106′, 107′, 108′ and 109′ consisting of a p-doped semiconductor material.

Analogously to the n-channel double-gate four-terminal semiconductor component 100, conductivity channels 120′ and 121′, separated by a barrier region 122′, for the minority charge carriers of the channel region 110′ can also be formed in the p-channel double-gate four-terminal semiconductor component 100′ by applying appropriately selected operating voltages to the gate electrodes 112 and 113.

A further relevant variation of the double-gate four-terminal semiconductor component involves changing the shape of the channel region. Such an embodiment will be described below with reference to FIG. 9.

FIG. 9 shows an n-channel double-gate four-terminal semiconductor component 400 with diverging channel arms in plan view.

The double-gate four-terminal semiconductor component 400 also comprises, analogously to the double-gate four-terminal semiconductor component 100, a substrate and a cover layer, which are not shown in FIG. 9 for the sake of simplicity, however.

As illustrated in FIG. 9, the double-gate four-terminal semiconductor component 400 differs from the double-gate four-terminal semiconductor component 100 essentially in the shape of the channel region. The double-gate four-terminal semiconductor component 400 comprises a channel region 410 that is fin-shaped in a central region, but at the ends of the channel region 410 has additional diverging channel arms 410.3-410.6, which extend in the transverse direction of the fin-shaped part of the channel region 410. This has the advantage that contact regions 406-409, which are each connected in an electrically conductive manner to one of the channel arms, are spatially further separated from each other so that crosstalk between the contact regions can be reduced.

Furthermore, the double-gate four-terminal semiconductor component 400 also comprises two gate electrodes 412 and 413, which are arranged opposite each other along longitudinal sides of the channel region 410 extending in a longitudinal direction, wherein an electrically conductive connection between the channel region 410 and gate electrodes 412 and 413 is prevented by an insulation layer 414 and 415 respectively. The gate electrodes 412 and 413 in plan view have rounded corners along a junction between the fin-shaped central region of the channel region 410 and one of the diverging channel arms.

Analogously to the double-gate four-terminal semiconductor component 100, by applying an operating voltage to the gate electrodes 412 and 413, conductivity channels (indicated by arrows 420 and 421) can also be formed within the channel region 410 in the double-gate four-terminal semiconductor component 400, which each electrically connect the contact region 406 and the contact region 408 as well as the contact region 407 and the contact region 409 together. In particular in the region of the channel region 410 designated by 480, an electrical field E runs parallel to the transverse direction of the channel region 410 due to the applied voltages. Therefore, in this region all statements already made for the conductivity channels in relation to FIG. 4 and FIGS. 5a-5d are also valid.

Furthermore, in the embodiment of the double-gate four-terminal semiconductor component 400 shown in FIG. 9, the channel arms 410.1 and 410.2 as well as 410.3 and 410.4 are separated from each other by a V-shaped recess. This is not absolutely essential, however.

Further, in the double-gate four-terminal semiconductor component 400, in plan view, corners of the gate electrodes 412 and 413 adjacent to one of the channel arms 410.3-410.6 and to one of the longitudinal sides 410.1 and 410.2 of the channel region are rounded off. These rounded corners promote current flow along the channel.

In the previously discussed embodiment, the channel region is homogeneously doped in each case. However, the operation of the double-gate field effect transistor can be further improved by using a special doping profile, as described below with reference to the exemplary embodiment of FIG. 10.

FIG. 10 shows a cross-section of an n-channel double-gate four-terminal semiconductor component 100″ with an adjusted doping profile 180 of a channel region 110″ in cross-section. The double-gate four-terminal semiconductor component 100″ is largely identical to the double-gate four-terminal semiconductor component 100 of FIG. 2. The elements already described in connection with FIG. 2 are provided with the same reference signs in FIG. 8 and are not described again in the following.

In contrast to the double-gate four-terminal semiconductor component 100, the double-gate four-terminal semiconductor component 100″ comprises a modified channel region 110″ in which doping with a dopant is not present in the entire channel region 110″. Instead, a region 110.1″ extending from the maximum height extent of the channel region to a first height section 140″ has no doping, but only a region 110.2″ extending from the height section 140″ to at least the cover layer is doped.

This is particularly advantageous because the electric field of the gate electrodes 112 and 113 is not completely homogeneous, particularly in the undoped region, due to edge effects not previously taken into account in the calculations, so that electrons in this region have a probability distribution that is greater toward the center of the channel region 110″. This results in at least one possibility of unintentional crosstalk between the conductivity channels of the channel region 110″. The undoped region 110″.1 prevents such crosstalk.

An advantageous possible use of the double-gate four-terminal semiconductor component is provided by logic circuits consisting of multiple transistors, since two conventional transistors can be implemented with a double-gate four-terminal semiconductor component. An example of such a logic circuit is a NAND gate. A NAND gate circuit design and its implementation by means of a double-gate four-terminal semiconductor component is described below with reference to FIGS. 11a and 11b.

FIG. 11a shows a circuit diagram of a NAND gate 700′ in CMOS technology from the prior art.

The NAND gate comprises a p-channel circuit block 710′ and an n-channel circuit block 720′, each of which is connected to two input channels labeled E1 and E2.

The p-channel circuit block 710′ comprises two p-channel field effect transistors 710.2′ and 710.4′, which are interconnected in parallel. In this configuration, source electrodes S1′ and S2′ of both transistors 710.2′ and 710.4′ are connected to a supply voltage V_{DD}. Furthermore, drain electrodes D1′ and D2′ of both transistors 710.2′ and 710.4′ are connected via a common line to an output channel A, and to the n-channel circuit block 720′. A gate electrode labeled G1′ of transistor 710.2′ is also connected to input channel E2 and a gate electrode G2′ of transistor 710.4 is connected to input channel E1.

The n-channel circuit block 720′ comprises two n-channel field effect transistors 720.2′ and 720.4′, which are connected in series with each other. A source electrode S3′ of transistor 720.2′ is connected to the drain electrodes D1′ and D2′ of transistors 710.2′ and 710.4′ of the p-channel circuit block 710′. Furthermore, a drain electrode D3′ of transistor 720.2 is connected to a source electrode S4′ of transistor 720.4′. A drain electrode D4′ of transistor 720.4′ is connected to a reference voltage, here the earth. Furthermore, a gate electrode G3′ of transistor 720.2′ is also connected to input channel E1′ and a gate electrode G4′ of transistor 720.4 is connected to input channel E2′.

In FIG. 11b below, an implementation of the NAND gate by means of double-gate four-terminal semiconductor components is described.

FIG. 11b shows the NAND gate from FIG. 9a realized with a p-channel double-gate four-terminal semiconductor component 710 and an n-channel double-gate four-terminal semiconductor component 720.

The two double-gate four-terminal semiconductor components 710 and 720 are shown in plan view and omitting the substrate and cover layer for simplification. Thus, only gate electrodes, channel region and contact regions are shown.

In the example, the contact regions of both semiconductor components 710 and 720 are interconnected in such a way that each of the semiconductor components functions as a bi-field effect transistor.

The circuit part 710′ with the two transistors 710.2′ and 710.4′ is realized by the p-channel double-gate four-terminal semiconductor component 710. For this purpose, the input channel E1 is connected to a gate electrode G2 and the input channel E2 is connected to a gate electrode G1 of the p-channel double-gate four-terminal semiconductor component 710. Furthermore, source contact regions S1 and S2 of the semiconductor component 710 are connected to the supply voltage in the same way as circuit 700. Furthermore, drain contact regions D1 and D2 are connected to the output channel A and to a source contact region S3 of the n-channel double-gate four-terminal semiconductor component 720.

The two transistors 720.2 and 720.4 are realized in circuit 700 by the n-channel double-gate four-terminal semiconductor component 720. Here, the input channel E1 is connected to a gate electrode G3 and the input channel E2 is connected to a gate electrode G4 of the n-channel double-gate four-terminal semiconductor component 720. Furthermore, a drain contact region D3 is connected to a source contact region S4 of the n-channel double-gate four-terminal semiconductor component 720 and a drain contact region D4 is connected to earth.

The CMOS circuit shown in FIG. 11a and FIG. 11b is only an example of circuits in which double-gate four-terminal semiconductor components can be advantageously used. In addition to CMOS circuits, it is also possible to use double-gate four-terminal semiconductor components in other metal oxide semiconductor circuits, such as NMOS or PMOS circuits.

What is claimed is:

1. A double-gate four-terminal semiconductor component, comprising
a substrate;
an electrically insulating cover layer on the substrate;
a fin-type channel region situated above the substrate and composed of a doped semiconductor material of a first conductivity type having two mutually opposite longitudinal sides extending along a longitudinal direction of the channel region, the channel region having a first end and a second end in the longitudinal direction;
a first and a second gate electrode, which are situated on the cover layer and are arranged opposite one another each on one of the longitudinal sides of the channel region and are each electrically insulated from the longitudinal sides by an insulation layer;
a first and a second contact region situated on the cover layer and composed of a semiconductor material of a second conductivity type, which are each arranged next to one of the gate electrodes toward the first end in the longitudinal direction of the channel region, each of the two contact regions being electrically conductively connected to the channel region and being electrically insulated from the adjacent gate electrode an insulation layer;
a third and a fourth contact region situated on the cover layer and composed of a semiconductor material of the second conductivity type, which are each arranged next to one of the gate electrodes toward the second end in the longitudinal direction of the channel region, each of the two contact regions being electrically conductively connected to the channel region and being electrically insulated from the adjacent gate electrode by an insulation layer, wherein
a transverse extent of the channel region in a transverse direction is dimensioned such that in a first operating state, in which a first and a second operating voltage are respectively applied to the gate electrodes, two conductivity channels of the second conductivity type separated by a barrier region in the transverse direction of the channel region are formed.

2. The double-gate four-terminal semiconductor component as claimed in claim 1, wherein
the first and third contact region are arranged as source contact regions on a first longitudinal side of the channel region, and
the second and fourth contact region are arranged as drain contact regions on a longitudinal side of the channel region opposite the first longitudinal side,
the transverse extent of the channel region and its doping are selected such that in a second operating state, in which a third and a fourth operating voltage are applied to each of the gate electrodes, the conductivity channels can be coupled to each other by a tunnel current of minority charge carriers through the barrier region.

3. The double-gate four-terminal semiconductor component as claimed in claim 1, wherein
the first end of the channel region is a source end and the first and second contact region are source contact regions; and
the second end of the channel region is a drain end and the third and fourth contact region are drain contact regions.

4. The double-gate four-terminal semiconductor component as claimed in claim 3, wherein the transverse extent of the channel region and its doping are selected such that in a second operating state, in which a third and a fourth operating voltage are applied to each of the gate electrodes, the conductivity channels can be coupled to each other by a tunnel current of minority charge carriers through the barrier region.

5. The double-gate four-terminal semiconductor component as claimed in claim 1, wherein the channel region has a height extent perpendicular to the cover layer and a doping profile of the channel region has a doping starting from the substrate only up to a first height extent, and a height section from the first height extent to the maximum height extent of the channel region is undoped.

6. The double-gate four-terminal semiconductor component as claimed in claim 1, wherein the channel region at each of the first end and the second end has two channel arms that diverge in the transverse direction of the channel region, which are electrically insulated by means of an insulation layer from the gate electrode and to the end of which one of the contact regions is electrically conductively connected.

7. The double-gate four-terminal semiconductor component as claimed in claim 6, wherein in a plan view of the double-gate four-terminal semiconductor component, corners of the gate electrodes, which adjoin a channel arm and a longitudinal side of the channel region are rounded off.

8. The double-gate four-terminal semiconductor component as claimed in claim 1, wherein the cover layer has a recess and the channel region is arranged at least partially in the recess and with direct contact to the substrate.

9. The double-gate four-terminal semiconductor component as claimed in claim 1, wherein the cover layer is designed in the form of a continuous cover layer on the substrate and the channel region is arranged on the cover layer.

10. The double-gate four-terminal semiconductor component as claimed in claim 1, wherein a dopant density of a conductivity doping of the channel region for achieving the first conductivity type is in the range between 10¹⁵ cm⁻³ and 10¹⁸ cm⁻³.

11. The double-gate four-terminal semiconductor component as claimed in claim 1, wherein the transverse extent of the channel region is in the range between 5 nm and 20 nm.

12. The double-gate four-terminal semiconductor component as claimed in claim 1, wherein the gate electrodes are arranged along the longitudinal sides of the channel region on a length, the size of which is greater than or equal to the sum of a coherence length of a wave function of the minority charge carriers within the channel region and double the shielding length of boundary fields generated by the contact regions within the gate electrode.

13. A metal-oxide semiconductor logic circuit, comprising
at least one p-channel or n-channel double-gate four-terminal semiconductor component, wherein the double-gate four-terminal semiconductor component comprises:
a substrate;
an electrically insulating cover layer on the substrate;
a fin-type channel region situated above the substrate and composed of a doped semiconductor material of a first conductivity type having two mutually opposite longitudinal sides extending along a longitudinal direction of the channel region, the channel region having a first end and a second end in the longitudinal direction;
a first and a second gate electrode, which are situated on the cover layer and are arranged opposite one another each on one of the longitudinal sides of the channel region and are each electrically insulated from the longitudinal sides by an insulation layer;
a first and a second contact region situated on the cover layer and composed of a semiconductor material of a second conductivity type, which are each arranged next to one of the gate electrodes toward the first end in the longitudinal direction of the channel region, each of the two contact regions being electrically conductively connected to the channel region and being electrically insulated from the adjacent gate electrode by an insulation layer, and
a third and a fourth contact region situated on the cover layer and composed of a semiconductor material of the second conductivity type, which are each arranged next to one of the gate electrodes toward the second end in the longitudinal direction of the channel region, each of the two contact regions beings electrically conductively connected to the channel region and being electrically insulated from the adjacent gate electrode by an insulation layer, wherein
a transverse extend of the channel region in a transverse direction is dimensioned such that in a first operating state, in which a first and a second operating voltage are respectively applied to the gate electrodes, two conductivity channels of the second conductivity type separated by a barrier region in the transverse direction of the channel region are formed,
the first end of the channel region is a source end and the first and second contact region are source contact regions;
the second end of the channel region is a drain end and the third and fourth contact regions are drain contact regions.
